(19) United States
(12) Patent Application Publication
(10) Pub. No.: US 2026/0173446 A1
(43) Pub. Date: Jun. 18, 2026

(54) SILICIDE REGIONS IN STACKING TRANSISTORS AND METHODS OF FORMING

(71) Applicant: Taiwan Semiconductor Manufacturing Co., Ltd., Hsinchu (TW)

(72) Inventors: Shih-Jung Ho, Hsinchu (TW); Kuan-Kan Hu, Hsinchu (TW); Ku-Feng Yang, Baoshan Township (TW); Szuya Liao, Zhubei (TW)

(21) Appl. No.: 18/984,255

(22) Filed: Dec. 17, 2024

(51) Int. Cl. H10D 30/67; H10D 30/00; H10D 30/01; H10D 30/43; H10D 62/10; H10D 84/83

(52) U.S. Cl. CPC H10D 30/6713; H10D 30/0198; H10D 30/43; H10D 30/502; H10D 30/6735; H10D 30/6757; H10D 62/121; H10D 84/832

(57) ABSTRACT

A semiconductor device includes a first source/drain region; a first silicide region on the first source/drain region; first nanostructures adjacent to the first source/drain region; a second source/drain region overlapping the first source/drain region; and a second silicide region on the second source/drain region. The first silicide region comprises a first metal that is different from a second metal comprised by the second silicide region.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example stacking transistor in accordance with some embodiments.

FIGS. 2 through 5, 6A, 6B, 7 through 14, 15A, 15B, and 16 are views of intermediate stages in the manufacturing of stacking transistors in accordance with some embodiments.

FIGS. 17A and 17B are cross-sectional views of example stacking transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Stacking transistor structures, such as CFETs, and the method of forming the same are provided. The stacking transistor structure includes two transistors that are vertically stacked and that are of opposite types (e.g., an n-type transistor and a p-type transistor that are vertically stacked). In various embodiments, silicide regions of the n-type transistor are made of a different material than silicide regions of the p-type transistor. Specifically, the materials of the silicide regions may be chosen to provide a lower barrier height to each of the n-type and the p-type source/drain regions. As a result, source/drain contact resistance in the resulting stacking transistor can be reduced, and device performance can be improved. Further, various methods use the stacking configuration of the n-type and p-type transistors to form silicide regions of different materials without significantly complicating the manufacturing process.

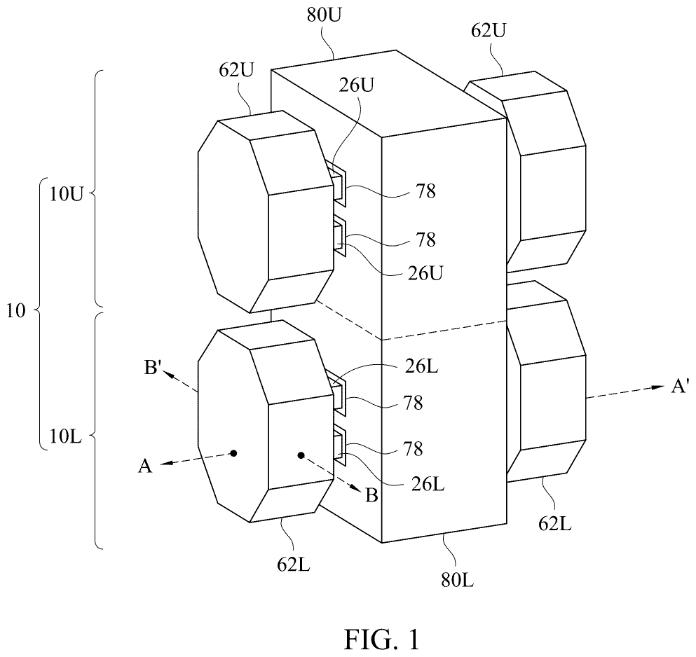

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of a stacking transistor and in a direction of, for example, a current flow between the source/drain regions 62 of the stacking transistor. Cross-section B-B′ is a vertical cross-section that is perpendicular to cross-section A-A′ and extends through the source/drain regions 62 of the stacking transistor. Subsequent figures may refer to these reference cross-sections for clarity.

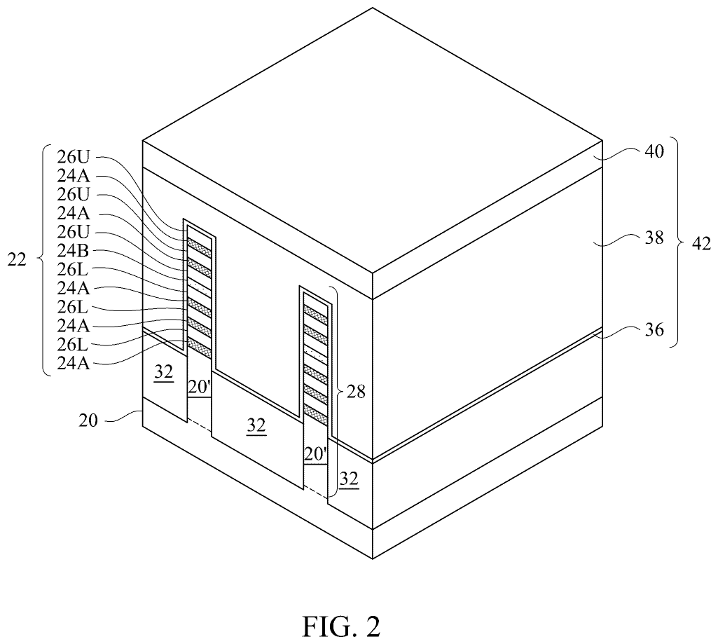

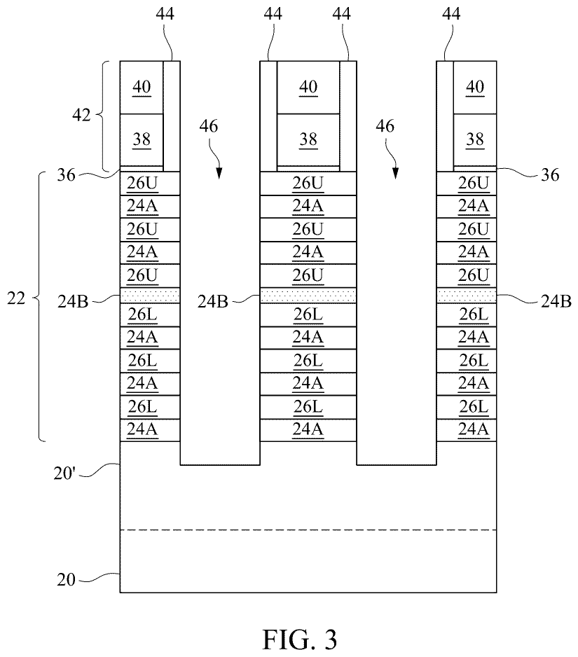

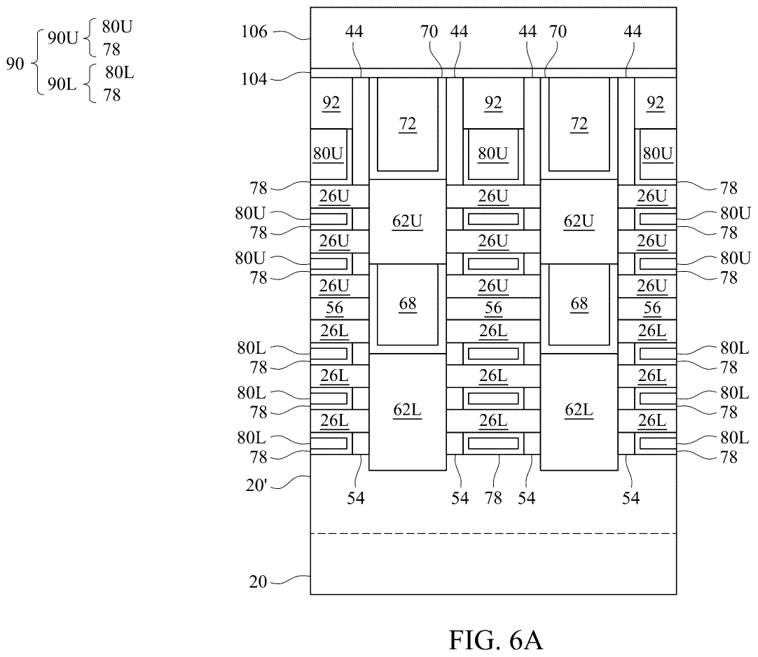

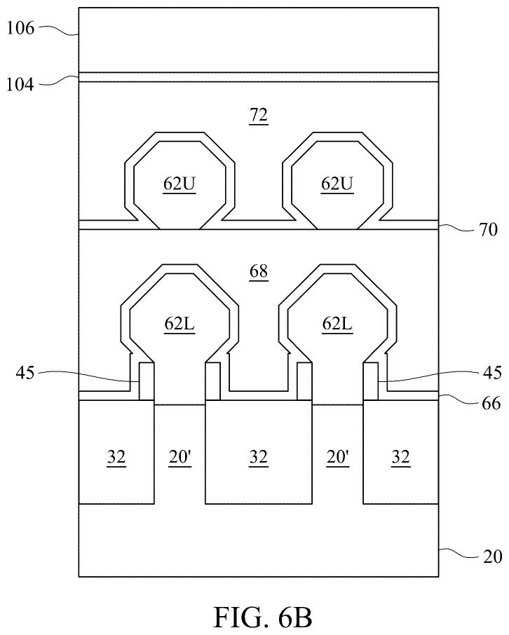

FIGS. 2 through 15B illustrate perspective and the cross-sectional views of intermediate stages in the formation of stacking transistors (as schematically represented in FIG. 1) in accordance with some embodiments. In subsequent discussion, FIGS. 3, 4, 5, 6A, and 16 illustrate the vertical cross-sectional views along a similar cross-section as vertical reference cross-section A-A′ in FIG. 1. FIGS. 6B, 7, 8, 9, 10, 11, 12, 13, 14, 15A, and 15B illustrate the cross-sectional views along a similar cross-section as the vertical reference cross-section B-B′ in FIG. 1.

In FIG. 2, a perspective view of a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20, also referred to as semiconductor fins 20′) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. In some embodiments, the first semiconductor material of the dummy nanostructures 24A and the second semiconductor material of the dummy nanostructures 24B may be made of a same semiconductor material with different compositions of elements. For example, both the first semiconductor material of the dummy nanostructures 24A and the second semiconductor material of the dummy nanostructures 24B may be made of silicon germanium with different germanium concentrations. The first and second semiconductor materials may be selected from the candidate semiconductor materials of the substrate 20. The first and second semiconductor materials have a high etching selectivity to one another. As such, the dummy semiconductor nanostructures 24B may be removed at a faster rate than the dummy semiconductor nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, the dummy nanostructures 24A are formed of silicon germanium, the semiconductor nanostructures 26 are formed of silicon, and the dummy nanostructures 24B may be formed of germanium or silicon germanium with a higher germanium atomic percentage than the semiconductor nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20′, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers 45 (see FIG. 6B) may also be formed as part of forming the gate spacers 44.

Subsequently, source/drain recesses 46 are formed in semiconductor strips 28. The source/drain recesses 46 are formed through etching, and may extend through the multi-layer stacks 22 and into the semiconductor strips 20′. The bottom surfaces of the source/drain recesses 46 may be at a level above, below, or the same as the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

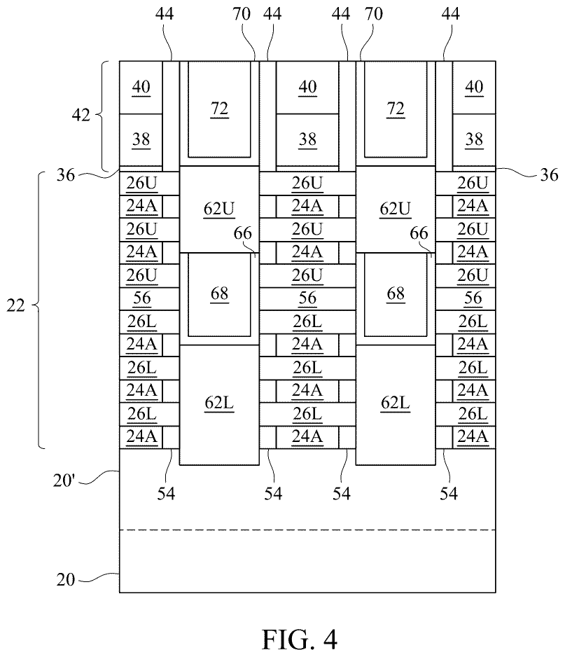

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments, removing the dummy nanostructures 24B may etch exposed surfaces of the semiconductor nanostructures 26, and may further widen a space between the lower semiconductor nanostructures 26L collectively) and the upper semiconductor nanostructures 26U (collectively). In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs. Because removing the dummy nanostructures 24B may etch and widen a space between the middle semiconductor nanostructures, the dielectric isolation layers 56 may be wider than the removed, dummy nanostructures 24B.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As also illustrated by FIG. 4, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower epitaxial source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. For example, the upper epitaxial source/drain regions 62U may be n-type and the lower epitaxial source/drain regions 62L may be p-type. Alternatively, the upper epitaxial source/drain regions 62U may be p-type and the lower epitaxial source/drain regions 62L may be n-type. The upper epitaxial source/drain regions 62U may be in-situ doped, and/or may be implanted, with an n-type or p-type dopant. Adjacent upper epitaxial source/drain regions 62U may remain separated after the epitaxy process or may be merged.

After the upper epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for the second CESL 70 and the second ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the masks 40 (if present) or the dummy gates 38 are exposed through the second ILD 72. In the illustrated embodiment, the masks 40 remain after the removal process. In other embodiments, the masks 40 are removed such that the top surfaces of the dummy gates 38 are exposed through the second ILD 72.

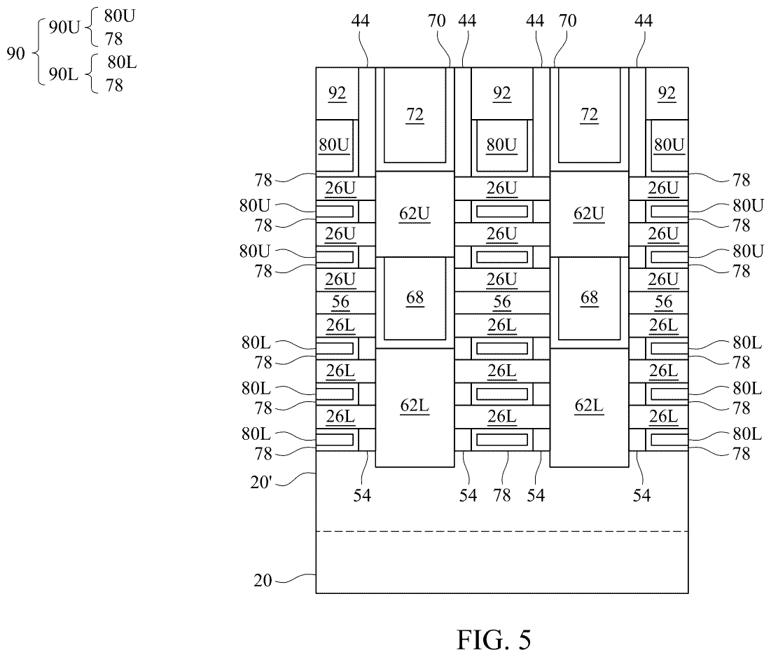

FIG. 5 illustrates a replacement gate process to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

As also shown in FIG. 5, gate masks 92 are formed over the gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

FIGS. 6A through 15B illustrate cross-sectional views of various intermediate steps of forming source/drain contacts to the upper epitaxial source/drain regions 62U and the lower epitaxial source/drain regions 62L. Referring first to FIGS. 6A and 6B, an ESL 104 and a third ILD 106 are formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like. The ESL 104 and the third ILD 106 may be used to help define a shape of the subsequently formed source/drain contacts.

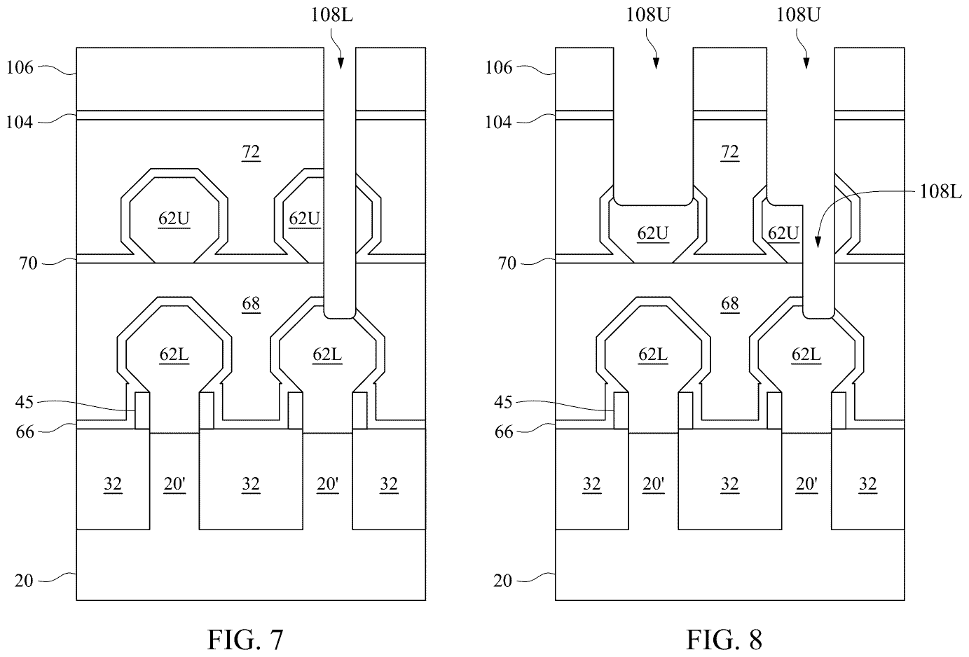

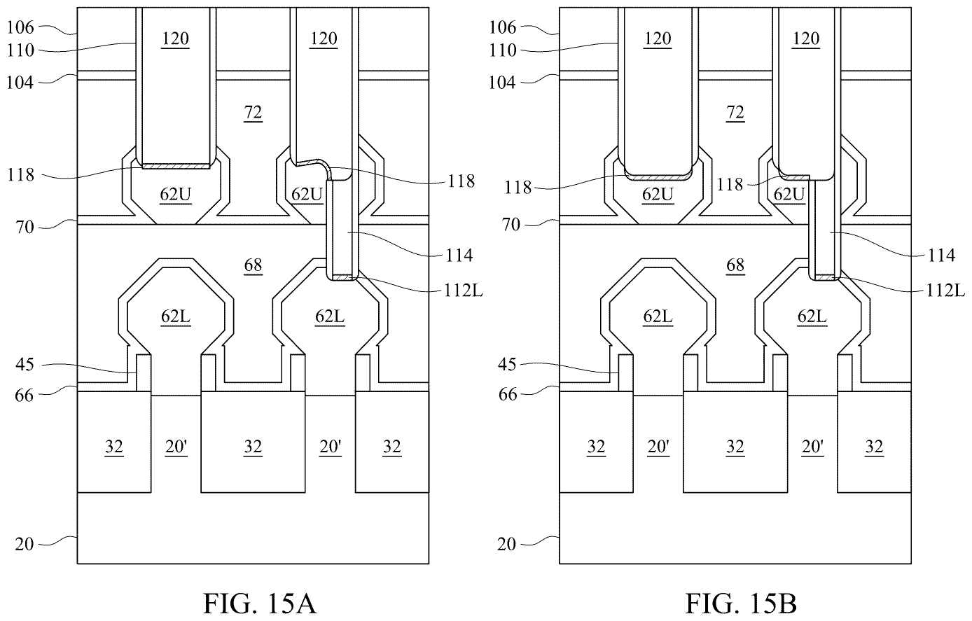

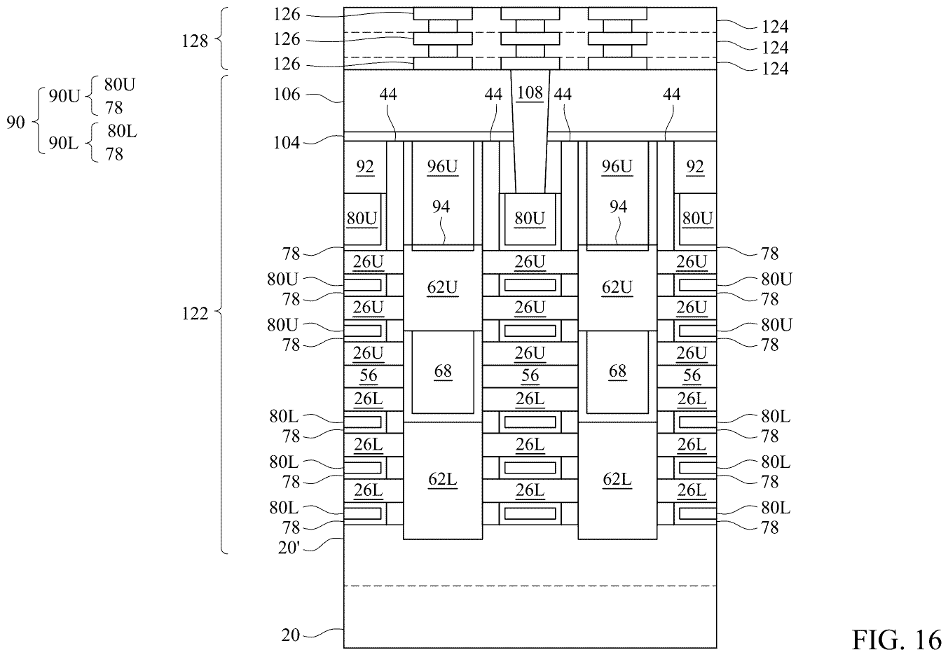

In FIGS. 7 and 8, upper source/drain contact openings 108U and lower source/drain contact openings 108L are formed to expose (and optionally extend into) the upper epitaxial source/drain regions 62U and/or the lower epitaxial source/drain regions 62L. Specifically, the lower source/drain contact openings 108L extend through the third ILD 106, the ESL 104, the second ILD 72, the second CESL 70, the upper epitaxial source/drain regions 62U, the first ILD 68, and/or the first CESL 66 to expose and extend partially into the lower epitaxial source/drain regions 62L, and the upper source/drain contact openings 108U extend through the third ILD 106, the ESL 104, the second ILD 72, and the second CESL 70 to expose and extend partially into the upper epitaxial source/drain regions 62U. Each of the upper source/drain contact openings 108U may or may not be connected to one of the lower source/drain source/drain contact openings 108L. In areas where the upper and lower source/drain contact openings 108U and 108L are connected, the exposed upper and lower epitaxial source/drain regions 62U and 62L may be electrically connected together by source/drain contacts that are subsequently formed in the connected upper and lower source/drain contact openings 108U and 108L (see FIGS. 15A and 15B). The upper and lower source/drain contact openings 108U and 108L may be formed by a combination of sequential photolithography and etching processes. In the illustrated embodiments, the lower source/drain contact openings 108L are formed to prior to forming the upper source/drain contact openings 108U. Alternatively, this order may be reversed, and the upper source/drain contact openings 108U may be formed prior to forming the lower source/drain contact openings 108L.

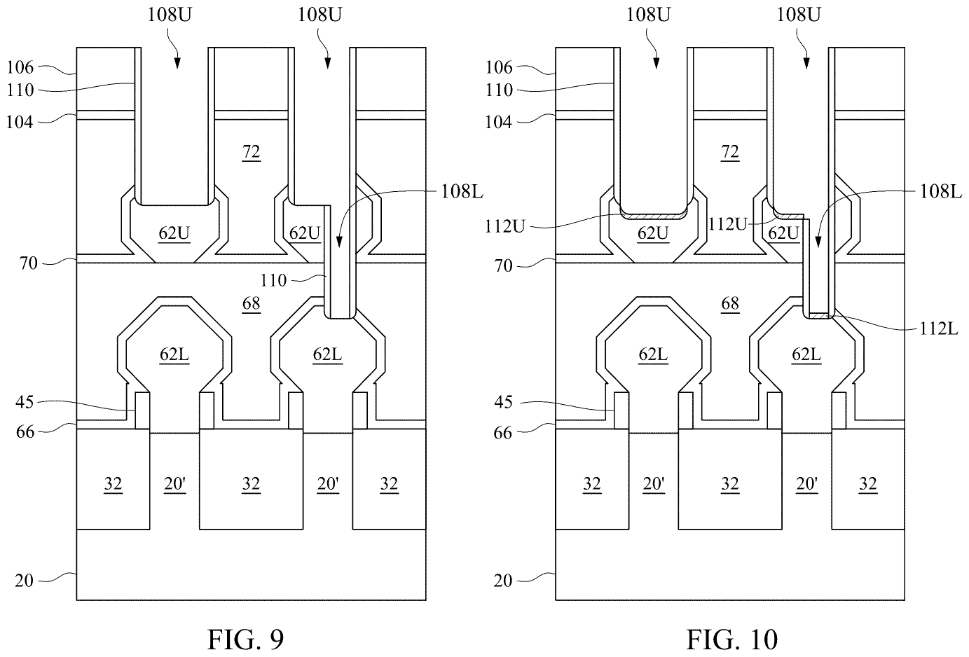

In FIG. 9, contact spacers 110 may be formed on sidewalls of the upper and lower source/drain contact openings 108U/108L. The contact spacers 110 may be formed of a low-k dielectric material. For example, the contact spacers 110 may comprise silicon oxide, silicon nitride, silicon oxynitride, silicon oxycarbonitride, combinations thereof or the like. The contact spacers 110 may be formed by conformally depositing an insulating material layer (not explicitly illustrated) by CVD, ALD, or the like. Then, lateral portions of the insulating material layer may be etched away by an anisotropic etching process, such as a plasma-based dry etch, thereby forming the contact spacers 110. The contact spacers 110 help protect the material of the first ILD 68, the second ILD 72, and/or the third ILD 106 during subsequent processing steps. Further, the contact spacers 110 may be used to improve isolation of the subsequently formed source/drain contacts against adjacent features. In some embodiments, the contact spacers 110 can be omitted.

In FIG. 10, lower silicide regions 112L and upper silicide regions 112U are formed on exposed surfaces of the lower epitaxial source/drain regions 62L and the upper epitaxial source/drain regions 62U, respectively. Although referred to as silicides, the upper and lower silicide regions 112U and 112L may be any metal-semiconductor alloy regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like.

The upper and lower silicide regions 112U and 112L can be formed by depositing a metal in the upper and lower source/drain contact openings 108U and 108L and then performing a thermal anneal process to react the metal with the semiconductor material of the upper and lower epitaxial source/drain regions 62U and 62L. The resulting upper and lower silicide regions 112U and 112L may comprise the deposited metal. The upper and lower silicide regions 112U and 112L may be formed simultaneously (e.g., during a same process) and each comprise the same metal element. The metal can be selected based on a conductivity type of the lower epitaxial source/drain regions 62L to provide a relatively low barrier height to the lower epitaxial source/drain regions 62L. For example, in embodiments where the lower epitaxial source/drain regions 62L are p-type regions, the metal of the upper and lower silicide regions 112U and 112L may be cobalt, vanadium, niobium, nickel, tungsten, magnesium, iron, cobalt, rhodium, palladium, ruthenium, rhenium, platinum, iridium, or osmium. Alternatively, in embodiments where the lower epitaxial source/drain regions 62L are n-type regions, the metal of the upper and lower silicide regions 112U and 112L may be titanium, chromium, tantalum, molybdenum, zirconium, hafnium, scandium, yttrium, holmium, terbium, gadolinium, lutetium, dysprosium, erbium, or ytterbium. In various embodiments, a barrier height difference between the lower silicide regions 112L and the lower epitaxial source/drain regions 62L may be less than 0.4 electron volts (eV), which advantageously allows for a decrease in source/drain contact resistance of the resulting device and improved device performance. The metal can be deposited by a deposition process such as ALD, CVD, PVD, or the like. After the thermal anneal process, a cleaning process, such as a wet clean, may be performed to remove any residual metal from the upper and lower contact openings 108U and 108L, such as from surfaces of the upper and lower silicide regions 112U and 112L. In subsequent process steps, the upper silicide regions 112U may be removed and replaced with another material. As such, the upper silicide regions 112U may also be referred to as sacrificial silicide regions.

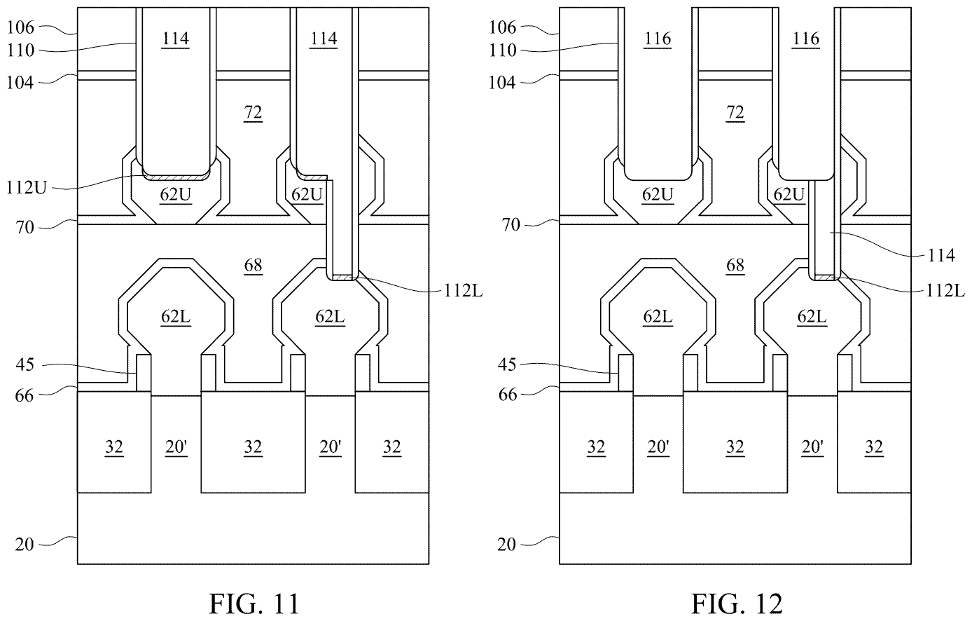

Next, in FIG. 11, source/drain contacts 114 are formed in the upper and lower source/drain contact openings 108U and 108L to electrically couple to the upper and lower epitaxial source/drain regions 62U and 62L. As an example to form the source/drain contacts 114, a liner (not separately illustrated), such as a diffusion barrier layer, an adhesion layer, or the like, and a conductive material are formed in the upper and lower source/drain contact openings 108U and 108L. The liner may include titanium, titanium nitride, tantalum, tantalum nitride, or the like. The conductive material may be cobalt, ruthenium, molybdenum, tungsten, copper, a copper alloy, silver, gold, aluminum, nickel, or the like that is formed by a plating process, PVD, CVD, ALD, or the like. A removal process may be performed to remove excess material from the top surfaces of the third ILD 106. The remaining liner and conductive material form the source/drain contacts 114 in the upper and lower source/drain contact openings 108U and 108L. In some embodiments, a planarization process such as a CMP, an etch-back process, combinations thereof, or the like is utilized. After the planarization process, the top surfaces of the source/drain contacts 114, the contact spacers 110, and the third ILD 106 are substantially coplanar (within process variations). Further, in embodiments where the contact spacers 110 are omitted, the source/drain contacts 114 (e.g., the liners of the source/drain contacts 114) may be formed in direct contact with sidewalls of the third ILD 106, the ESL 104, the second ILD 72, and/or the second CESL 70.

In FIGS. 12 through 14, the upper silicide regions 112U are replaced with upper silicide regions 118, which comprise a different metal element than the lower silicide regions 112L. Referring first to FIG. 12, an etching process is performed to recess the source/drain contacts 114 and remove the upper silicide regions 112U, exposing the upper epitaxial source/drain regions 62U. Recessing the source/drain contacts 114 may be performed by an etching process that selectively etches the source/drain contacts 114 at a faster rate than the third ILD 106, the contact spacers 110, and the upper epitaxial source/drain regions 62U. Subsequently, the upper silicide regions 112U are removed from the source/drain contact openings 116 by a timed etching process, for example. The timed etching process may be a selective process that selectively etches the upper silicide regions 112U at a faster rate than the third ILD 106, the contact spacers 110, and the source/drain contacts 114. In some embodiments, removing the upper silicide regions 112U may also etch upper portions of the upper epitaxial source/drain regions 62U that are exposed by the source/drain contact openings 116. After removing the upper silicide regions 112U, lower portions of the source/drain contacts 114 remain and are electrically connected to the lower epitaxial source/drain regions 62L through the lower silicide regions 112L, and the source/drain contacts 114 may be referred to as lower source/drain contacts 114 hereinafter.

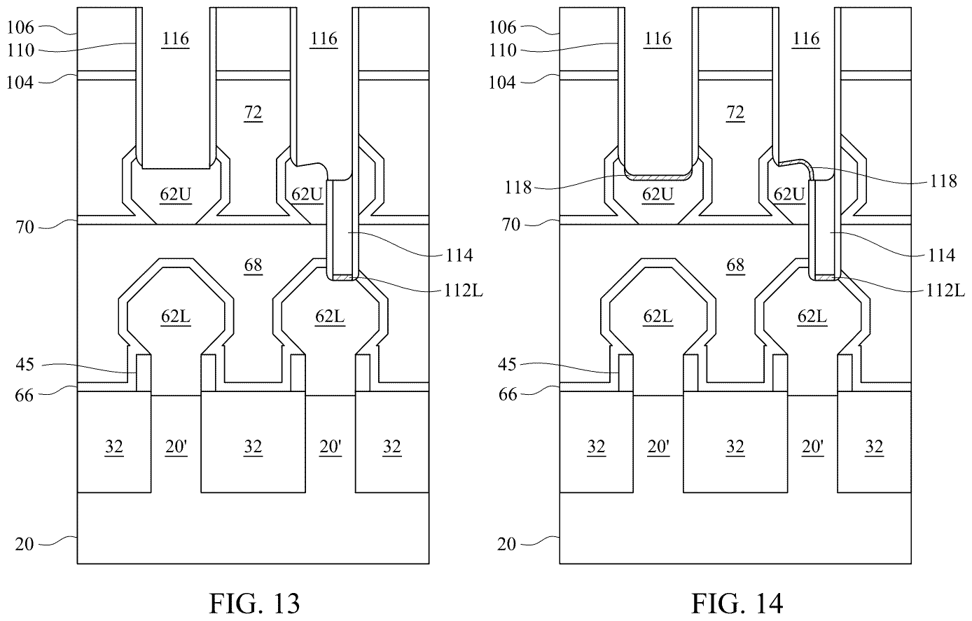

In FIG. 13, an optional epitaxial regrowth process may be performed to regrow a material of the upper epitaxial source/drain regions 62U. The epitaxial regrowth process may be similar as those discussed above with respect to the upper epitaxial source/drain regions 62U, and the regrown material may be the same as the upper epitaxial source/drain regions 62U. In some embodiments, the epitaxial regrowth process is a low-temperature process (e.g., performed at a temperature less than 400° C.) to avoid thermal damage of the upper and lower epitaxial source/drain regions 62U and 62L. The epitaxial regrowth process may or may not be selective to a material of the upper epitaxial source/drain regions 62U. The epitaxial regrowth process may compensate for inadvertent, over-etching of the upper epitaxial source/drain region 62U from removal of the upper silicide regions 112U. As a result of the epitaxial regrowth process, the upper epitaxial source/drain regions 62U may overlap the contact spacers 110 and/or the lower source/drain contacts 114. The regrowth process is optional and may be omitted in embodiments where the remaining volume of the upper epitaxial source/drain regions 62U is sufficient after removing the upper silicide regions 112U (see e.g., FIG. 15B).

In FIG. 14, upper silicide regions 118 are formed on exposed surfaces of the upper epitaxial source/drain regions 62U. Although referred to as silicides, the upper silicide regions 118 may be any metal-semiconductor alloy regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like.

The upper silicide regions 118 can be formed by depositing a metal in the source/drain contact openings 116 and then performing a thermal anneal process. The thermal anneal process reacts the metal with the semiconductor material of the upper epitaixial source/drain regions 62U. The upper silicide regions 118 may be made from a different metal element and have a different composition than the lower silicide regions 112L. Specifically, the metal can be selected based on a conductivity type of the upper epitaxial source/drain regions 62U to provide a relatively low barrier height to the upper epitaxial source/drain regions 62U. For example, in embodiments where the upper epitaxial source/drain regions 62U are p-type regions, the metal of the upper silicide regions 118 may be cobalt, vanadium, niobium, nickel, tungsten, magnesium, iron, cobalt, rhodium, palladium, ruthenium, rhenium, platinum, iridium, or osmium. Alternatively, in embodiments where the upper epitaxial source/drain regions 62U are n-type regions, the metal of the upper silicide regions 118 may be titanium, chromium, tantalum, molybdenum, zirconium, hafnium, scandium, yttrium, holmium, terbium, gadolinium, lutetium, dysprosium, erbium, or ytterbium. In various embodiments, a barrier height difference between the upper silicide regions 118 and the upper epitaxial source/drain regions 62U may be less than 0.4, which advantageously allows for a decrease in source/drain contact resistance of the resulting device and improved device performance. The metal can be deposited by a deposition process such as ALD, CVD, PVD, or the like. After the thermal anneal process, a cleaning process, such as a wet clean, may be performed to remove any residual metal from the source/drain contact openings 116, such as from surfaces of the upper silicide regions 118. Because the upper silicide regions 118 and the lower silicide regions 112L are formed in separate steps and of separate materials, each of the upper silicide regions 118 and the lower silicide regions 112L can be formed to have a reduced barrier height to a respective one of the upper and lower epitaxial source/drain region 62U and 62L. This allows source/drain contact resistance to each of the upper and lower epitaxial source/drain regions 62U and 62L to be effectively reduced in the resulting device. Further, the described method uses the stacked, configuration of stacking transistors, to separately form the upper silicide regions 118 and the lower silicide regions 112 without adding excessive masking steps to the overall process.

As illustrated, the upper silicide regions 118 may contact and connect disparate portions of the contact spacers 110. For example, an upper silicide region 118 may extend from a bottom of an upper contact spacer 110 (e.g., in the second ILD 72 and disposed around a subsequently formed, upper source/drain contact 120, see FIGS. 15A and 15B) to a top of a lower contact spacer 110 (e.g., in the first ILD 68 and disposed around a lower source/rain contact 114). Further, adjacent ones of the upper silicide regions 118 may have different bottom surface profiles. The profile of each of the upper silicide regions 118 may depend on a profile of the respective upper epitaxial source/drain region 62U in which it is formed. For example, in FIG. 14, the right, upper silicide region 118 has a convex, curved bottom profile while the left, upper silicide region 118 has a linear bottom profile. Similarly, bottom widths of adjacent upper silicide regions 118 may also be different depending on a width of the respective upper epitaxial source/drain region 62U in which it is formed.

Next, in FIGS. 15A and 15B, upper source/drain contacts 120 are formed in the source/drain contact openings 116 to electrically couple to the upper epitaxial source/drain regions 62U through the upper silicide regions 118. FIG. 15A illustrates an embodiment where an epitaxial regrowth process is performed to regrow a portion of the upper epitaxial source/drain regions 62U following the removal of the upper silicide regions 112U and prior to forming the upper silicide regions 118. FIG. 15B illustrates an embodiment where the epitaxial regrowth process is omitted. The upper silicide regions 118 may cover an entire bottom surface of the upper source/drain contact 120 (see left upper source/drain contact 120 in FIGS. 15A and 15B) or only partially cover a bottom surface of the upper source/drain contact (see right upper source/drain contact 120 in FIGS. 15A and 15B). In scenarios where the upper silicide regions 118 only partially covers a bottom surface of the upper source/drain contact, a width of the upper silicide region 118 may be less than a width of the bottom surface of the upper source/drain contact (see right upper source/drain contact 120 in FIGS. 15A and 15B).

As an example to form the upper source/drain contacts 120, a liner (not separately illustrated), such as a diffusion barrier layer, an adhesion layer, or the like, and a conductive material are formed in the source/drain contact openings 116. The liner may include titanium, titanium nitride, tantalum, tantalum nitride, or the like. The conductive material may be cobalt, ruthenium, molybdenum, tungsten, copper, a copper alloy, silver, gold, aluminum, nickel, or the like that is formed by a plating process, PVD, CVD, ALD, or the like. A removal process may be performed to remove excess material from the top surfaces of the third ILD 106. The remaining liner and conductive material form the upper source/drain contacts 120 in the source/drain contact openings 116. In some embodiments, a planarization process such as a CMP, an etch-back process, combinations thereof, or the like is utilized. After the planarization process, the top surfaces of the upper source/drain contacts 120, the contact spacers 110, and the third ILD 106 are substantially coplanar (within process variations).

The upper source/drain contacts 120 may also electrically couple to the lower epitaxial source/drain regions 62L through the lower source/drain contacts 114. For example, the upper source/drain contacts 120 and the lower source/drain contacts 114 may be in physical contact at a shared interface, and the upper source/drain contacts 120 and the lower source/drain contacts 114 may collectively electrically couple vertically stacked upper and lower epitaxial source/drain regions 62U and 62L together. The upper source/drain contacts 120 and the lower source/drain contacts 114 may be formed of a same material or different materials. In some embodiments, interfaces between the materials of the upper source/drain contacts 120 and the lower source/drain contacts 114 even when a same material is used to form the upper source/drain contacts 120 and the lower source/drain contacts 114. The interfaces between the materials of the upper source/drain contacts 120 and the lower source/drain contacts 114 may result from the upper source/drain contacts 120 and the lower source/drain contacts 114 being in separates processes with a vacuum break between forming the upper source/drain contacts 120 and forming the lower source/drain contacts 114. The interface between the upper source/drain contacts 120 and the lower source/drain contacts 114 may be disposed within the upper epitaxial source/drain regions 62U, such as at a level below a top surface of the upper epitaxial source/drain regions 62U and above a bottom surface of the upper epitaxial source/drain regions 62U. In some embodiments, a material of the lower source/drain contacts 114 may have a relatively low resistance, such as ruthenium, molybdenum, or the like, and the upper source/drain contacts 120 may be formed of a material with improved gap fill characteristics, such as tungsten, or the like. Other combinations of materials are possible for the upper source/drain contacts 120 and the lower source/drain contacts 114.

Because the lower source/drain contact 114 extends partially through some of the upper epitaxial source/drain regions, the volume of some of the upper epitaxial source/drain regions (e.g., left upper epitaxial source/drain region 62U) may be greater than others of the upper epitaxial source/drain regions (e.g., right upper epitaxial source/drain region 62U). For example, in a cross-sectional view, a width of some of the upper epitaxial source/drain regions (e.g., left upper epitaxial source/drain region 62U) may be greater than others of the upper epitaxial source/drain regions (e.g., right upper epitaxial source/drain region 62U). Further, the effective volume and/or cross-sectional widths of upper epitaxial source/drain regions 62U may be different (e.g., greater than or less than) that of lower epitaxial source/drain regions 62L. Specifically, the effective volume of each of the upper epitaxial source/drain regions 62U and/or lower epitaxial source/drain regions 62L may be configured based on a desired device type of the upper and/or lower transistor.

In FIG. 16, gate contacts 108 are formed to contact the upper gate electrodes 80U. The gate contacts 108 may be formed prior to or after forming the source/drain contacts 114/120. As an example to form the gate contacts 108, openings for the gate contacts 108 through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 in the openings.

A front-side interconnect structure 128 is formed on a device layer 122 (a layer comprising the stacking transistors, the gate contacts 108, and the upper and lower source/drain contacts 120 and 114). The front-side interconnect structure 128 includes dielectric layers 124 and layers of conductive features 126 in the dielectric layers 124. The dielectric layers 124 may include low-k dielectric layers formed of low-k dielectric materials. The dielectric layers 124 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 124 may also include polymer layers.

The conductive features 126 may include conductive lines and vias, which may be formed using damascene processes. Conductive features 126 may include metal lines and metal vias, which includes diffusion barriers and a copper containing material over the diffusion barriers. There may also be aluminum pads over and electrically connected to the metal lines and vias.

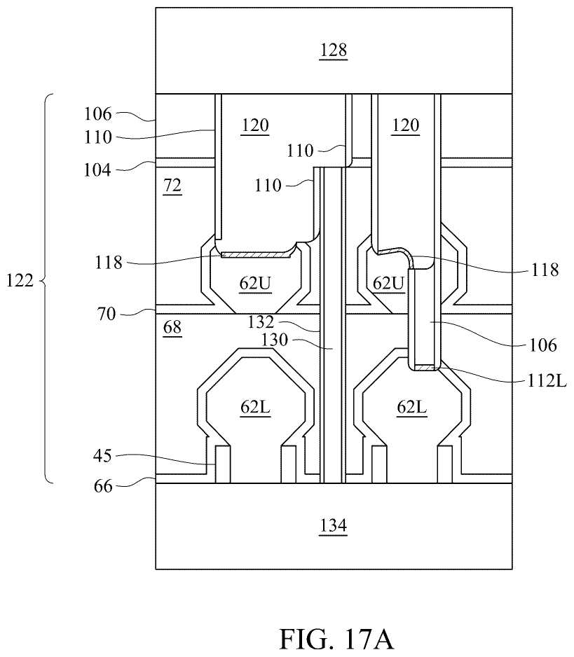

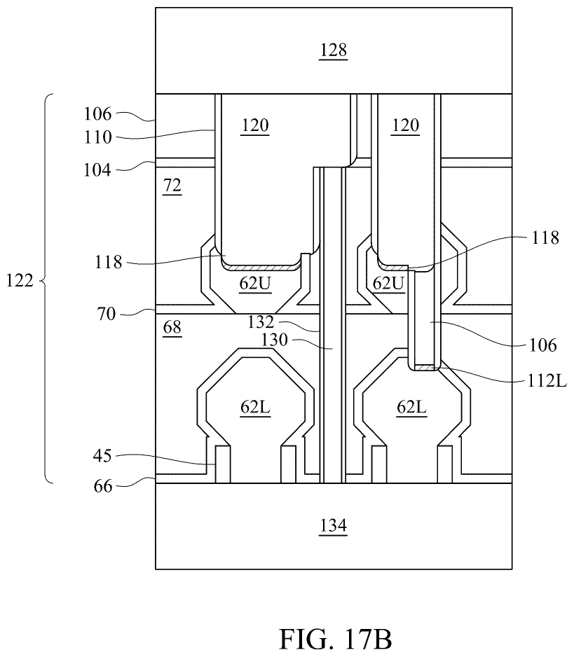

In some embodiments, contacts to the lower gate stacks 90L and the lower epitaxial source/drain regions 62L may be made through a backside of the device layer 122 (e.g., a side opposite to the front-side interconnect structure 128). For example, FIGS. 17A and 17B illustrate the device layer 122 between the front-side interconnect structure 128 and a backside interconnect structure 134. The backside interconnect structure 134 may be substantially similar to the front-side interconnect structure 128 as described above. In FIGS. 17A and 17B, like reference numerals indicate like elements formed by like processes as described above with FIGS. 15A and 15B, respectively. FIG. 17A illustrates an embodiment where an epitaxial regrowth process is performed to regrow a portion of the upper epitaxial source/drain regions 62U following the removal of the upper silicide regions 112U and prior to forming the upper silicide regions 118. FIG. 17B illustrates an embodiment where the epitaxial regrowth process is omitted.

Contact vias 130 having contact spacers 132 disposed on sidewalls thereof are formed to extend through at least partially through the device layer 122. The contact vias 130 may be formed of like materials and like processes as the upper and lower source/drain contacts 120 and 114, described above, and the contact spacers 132 may be formed of like materials and like processes as the contact spacers 110, described above. The contact vias 130 and the contact spacers 132 may be formed through the first CESL 66, the first ILD 68, the second CESL 70 and the second ILD 72 prior to forming the ESL 104 and the third ILD 106. The contact vias 130 may be electrically connected to the backside interconnect structure 134, and the contact vias 130 may also be electrically connected to front-side interconnect structure 128 (e.g., through the upper source/drain contacts 120). In this manner, interconnection between the front-side interconnect structure 128 and the backside interconnect structure 134 may be achieved.

Although various embodiments are described using a front-side source/drain contact 120 that electrically connects the upper epitaxial source/drain region 62U to the lower epitaxial source/drain region 62L, various embodiments may be applied to a backside source/drain contact instead of a front-side source/drain contact. For example, the various process steps described above in FIGS. 6A through 15B may be applied from a backside of the device layer 122 to provide a backside source/drain contact that electrically connects a lower epitaxial source/drain region 62L to an upper epitaxial source/drain region 62U. Silicide regions utilizing different materials may also be selectively made to the lower epitaxial source/drain region 62L and the upper epitaxial source/drain region 62U through a contact opening of the backside source/drain contact. Additionally, the backside source/drain contact may be formed prior to or after the frontside source/drain contacts.

In various embodiments, the n-type and p-type transistors utilize different materials for silicide regions that are specifically chosen to lower the barrier height to their respective source/drain regions. This approach reduces source/drain contact resistance in the stacking transistor, thereby enhancing overall device performance. The stacking configuration of these transistors allows for the formation of silicide regions with different materials without significantly complicating the manufacturing process.

In some embodiments, a semiconductor device includes a first source/drain region; a first silicide region on the first source/drain region; first nanostructures adjacent to the first source/drain region; a second source/drain region overlapping the first source/drain region; a second silicide region on the second source/drain region, wherein the first silicide region comprises a first metal that is different from a second metal comprised by the second silicide region; second nanostructures adjacent to the second source/drain region; a first gate structure around the first nanostructures; and a second gate structure overlapping the first gate structure and around the second nanostructures. In some embodiments, the first source/drain region has an opposite conductivity type than the second source/drain region. In some embodiments, a barrier height difference between the first silicide region and the first source/drain region is less than 0.4 eV. In some embodiments, a barrier height difference between the second silicide region and the second source/drain region is less than 0.4 eV. In some embodiments, the device further includes a lower source/drain contact connected to the first source/drain region through the first silicide region; and an upper source/drain contact connected to the second source/drain region through the second silicide region, wherein the upper source/drain contact overlaps the lower source/drain contact. In some embodiments, an interface between the upper source/drain contact and the lower source/drain contact is disposed within the second source/drain region. In some embodiments, the lower source/drain contact is made of a third metal, wherein the upper source/drain contact is made of a fourth metal that has a different composition than the third metal. In some embodiments, the lower source/drain contact is made of a third metal, wherein the upper source/drain contact is made of a fourth metal that has a same composition as the third metal.

In some embodiments, a method includes patterning a first opening through one or more dielectric layers to expose a first source/drain region and a second source/drain region, wherein the second source/drain region overlaps the first source/drain region; forming a first silicide region on the first source/drain region and a second silicide region on the second source/drain region in the first opening; forming a first source/drain contact in the first opening, over the first silicide region and the second silicide region; etching the first source/drain contact to define a second opening, the second opening exposing the second silicide region; replacing the second silicide region with a third silicide region on the second source/drain region in the second opening; and forming a second source/drain contact in the second opening, wherein the first source/drain contact is electrically coupled to the first source/drain region through the first silicide region, and wherein the second source/drain contact is electrically coupled to the second source/drain region through the second silicide region. In some embodiments, the first silicide region and the second silicide region each comprises a first metal that is different from a second metal comprised by the third silicide region. In some embodiments, the first metal is selected based on a conductivity type of the first source/drain region, and wherein the second metal is selected based on a conductivity type of the second source/drain region. In some embodiments, the first source/drain contact is electrically coupled to the second source/drain contact. In some embodiments, replacing the second silicide region with the third silicide region comprises: removing the second silicide region with an etching process, wherein the etching process further comprises etching the second source/drain region; and forming the third silicide region on the second source/drain region after the etching process. In some embodiments, the method further includes performing an epitaxial regrowth process on the second source/drain region prior to forming the third silicide region. In some embodiments, the first source/drain contact is made of a third metal, wherein the second source/drain contact is made of a fourth metal that has a different composition than the third metal. In some embodiments, the first source/drain contact is made of a third metal, wherein the second source/drain contact is made of a fourth metal that has a same composition as the third metal.

In some embodiments, a method includes patterning a first opening through one or more dielectric layers to expose a first source/drain region and a second source/drain region, wherein the second source/drain region overlaps the first source/drain region, and the second source/drain region has an opposite conductivity type than the first source/drain region; forming a first silicide region on the first source/drain region in the first opening, the first silicide region comprising a first metal; forming a first source/drain contact in the first opening and extending to the first silicide region; etching the first source/drain contact to define a second opening; forming a second silicide region on the second source/drain region in the second opening; and forming a second source/drain contact in the second opening and extending to the second silicide region. In some embodiments, the method further includes forming a third silicide region on the second source/drain region in the first opening, wherein etching the first source/drain contact exposes the third silicide region, and the third silicide region comprises the first metal; and performing an etching process to remove the third silicide region from the second opening prior to forming the second silicide region. In some embodiments, the etching process removes an upper portion of the second source/drain region, and wherein the method further comprises performing an epitaxial process to regrow a material of the second source/drain region. In some embodiments, the second silicide region comprises a second metal different from the first metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first source/drain region;
a first silicide region on the first source/drain region;
first nanostructures adjacent to the first source/drain region;
a second source/drain region overlapping the first source/drain region;
a second silicide region on the second source/drain region, wherein the first silicide region comprises a first metal that is different from a second metal comprised by the second silicide region;
second nanostructures adjacent to the second source/drain region;
a first gate structure around the first nanostructures; and
a second gate structure overlapping the first gate structure and around the second nanostructures.

2. The semiconductor device of claim 1, wherein the first source/drain region has an opposite conductivity type than the second source/drain region.

3. The semiconductor device of claim 1, wherein a barrier height difference between the first silicide region and the first source/drain region is less than 0.4 eV.

4. The semiconductor device of claim 1, wherein a barrier height difference between the second silicide region and the second source/drain region is less than 0.4 eV.

5. The semiconductor device of claim 1 further comprising:
a lower source/drain contact connected to the first source/drain region through the first silicide region; and
an upper source/drain contact connected to the second source/drain region through the second silicide region, wherein the upper source/drain contact overlaps the lower source/drain contact.

6. The semiconductor device of claim 5, wherein an interface between the upper source/drain contact and the lower source/drain contact is disposed within the second source/drain region.

7. The semiconductor device of claim 5, wherein the lower source/drain contact is made of a third metal, wherein the upper source/drain contact is made of a fourth metal that has a different composition than the third metal.

8. The semiconductor device of claim 5, wherein the lower source/drain contact is made of a third metal, wherein the upper source/drain contact is made of a fourth metal that has a same composition as the third metal.

9. A method comprising:
patterning a first opening through one or more dielectric layers to expose a first source/drain region and a second source/drain region, wherein the second source/drain region overlaps the first source/drain region;
forming a first silicide region on the first source/drain region and a second silicide region on the second source/drain region in the first opening;
forming a first source/drain contact in the first opening, over the first silicide region and the second silicide region;
etching the first source/drain contact to define a second opening, the second opening exposing the second silicide region;
replacing the second silicide region with a third silicide region on the second source/drain region in the second opening; and
forming a second source/drain contact in the second opening, wherein the first source/drain contact is electrically coupled to the first source/drain region through the first silicide region, and wherein the second source/drain contact is electrically coupled to the second source/drain region through the second silicide region.

10. The method of claim 9, wherein the first silicide region and the second silicide region each comprises a first metal that is different from a second metal comprised by the third silicide region.

11. The method of claim 10, wherein the first metal is selected based on a conductivity type of the first source/drain region, and wherein the second metal is selected based on a conductivity type of the second source/drain region.

12. The method of claim 9, wherein the first source/drain contact is electrically coupled to the second source/drain contact.

13. The method of claim 9, wherein replacing the second silicide region with the third silicide region comprises:
removing the second silicide region with an etching process, wherein the etching process further comprises etching the second source/drain region; and
forming the third silicide region on the second source/drain region after the etching process.

14. The method of claim 13, further comprising performing an epitaxial regrowth process on the second source/drain region prior to forming the third silicide region.

15. The method of claim 9, wherein the first source/drain contact is made of a third metal, wherein the second source/drain contact is made of a fourth metal that has a different composition than the third metal.

16. The method of claim 9, wherein the first source/drain contact is made of a third metal, wherein the second source/drain contact is made of a fourth metal that has a same composition as the third metal.

17. A method comprising:
patterning a first opening through one or more dielectric layers to expose a first source/drain region and a second source/drain region, wherein the second source/drain region overlaps the first source/drain region, and the second source/drain region has an opposite conductivity type than the first source/drain region;
forming a first silicide region on the first source/drain region in the first opening, the first silicide region comprising a first metal;
forming a first source/drain contact in the first opening and extending to the first silicide region;
etching the first source/drain contact to define a second opening;
forming a second silicide region on the second source/drain region in the second opening; and
forming a second source/drain contact in the second opening and extending to the second silicide region.

18. The method of claim 17 further comprising:
forming a third silicide region on the second source/drain region in the first opening, wherein etching the first source/drain contact exposes the third silicide region, and the third silicide region comprises the first metal; and
performing an etching process to remove the third silicide region from the second opening prior to forming the second silicide region.

19. The method of claim 18, wherein the etching process removes an upper portion of the second source/drain region, and wherein the method further comprises performing an epitaxial process to regrow a material of the second source/drain region.

20. The method of claim 17, wherein the second silicide region comprises a second metal different from the first metal.
